(19) United States
(12) Patent Application Publication
(10) Pub. No.: US 2025/0029959 A1
(43) Pub. Date: Jan. 23, 2025

(54) FULL-COLOR LED STRUCTURE AND PREPARATION METHOD OF FULL-COLOR LED STRUCTURE

(71) Applicant: Enkris Semiconductor, Inc., Suzhou (CN)

(72) Inventors: Liyang Zhang, Suzhou (CN); Kai Cheng, Suzhou (CN)

(21) Appl. No.: 18/512,837

(22) Filed: Nov. 17, 2023

(30) Foreign Application Priority Data
Jul. 17, 2023 (CN) 202310876207.4

(51) Int. Cl. H01L 25/075; H01L 33/00; H01L 33/38; H01L 33/62

(52) U.S. Cl. CPC H01L 25/0753; H01L 33/0093; H01L 33/382; H01L 33/62; H01L 2933/0016; H01L 2933/0066

(57) ABSTRACT

Provided are a full-color LED structure and a preparation method of a full-color LED structure. The full-color LED structure includes a first substrate, first-color light-emitting units, second-color light-emitting units, and third-color light-emitting units. The first-color light-emitting units and the second-color light-emitting units are disposed on a side of the first substrate, disposed in the same layer, and simultaneously prepared. The third-color light-emitting units are disposed on the side of the first-color light-emitting units and the second-color light-emitting units facing away from the first substrate, where a vertical projection of a third-color light-emitting unit on the first substrate does not overlap a vertical projection of a first-color light-emitting unit on the first substrate or a vertical projection of a second-color light-emitting unit on the first substrate.

### CROSS-REFERENCE TO RELATED APPLICATIONS

This application claims priority to Chinese patent application No. 202310876207.4 filed with the China National Intellectual Property Administration (CNIPA) on Jul. 17, 2023, the disclosure of which is incorporated herein by reference in its entirety.

### TECHNICAL FIELD

The present disclosure relates to the field of semiconductor technology and, in particular, to a full-color light-emitting diode (LED) structure and a preparation method of a full-color LED structure.

### BACKGROUND

In the related art, methods for achieving a full-color effect include full-color epitaxy, mass transfer, the combination of light of three colors, color conversion, and the like. However, in the full-color epitaxy, a device with three-color light-emitting diodes directly obtained through the epitaxy has low light emission efficiency; in the mass transfer, single-color light-emitting diodes are manufactured separately and then transferred, which has low transfer efficiency and a limited transfer yield; in the combination of lights of three colors, a red-light device has a size effect and relatively low light emission efficiency; and in the color conversion manner, an organic material in the photoresist is prone to aging and may cause a decrease in light emission efficiency due to wavelength conversion.

### SUMMARY

The present disclosure provides a full-color LED structure and a preparation method of a full-color LED structure, which can achieve a full-color effect and improve the light emission efficiency of a device.

According to the present disclosure, a full-color LED structure is provided.

The full-color LED structure includes a first substrate, first-color light-emitting units, second-color light-emitting units, and third-color light-emitting units.

The first-color light-emitting units and the second-color light-emitting units are disposed on a side of the first substrate, disposed in the same layer, and simultaneously prepared.

The third-color light-emitting units are disposed on the side of the first-color light-emitting units and the second-color light-emitting units facing away from the first substrate, and a vertical projection of a third-color light-emitting unit on the first substrate does not overlap a vertical projection of a first-color light-emitting unit on the first substrate or a vertical projection of a second-color light-emitting unit on the first substrate.

According to the present disclosure, a preparation method of a full-color LED structure is provided. The method includes the steps described below.

First-color light-emitting units and second-color light-emitting units are prepared on a side of a first substrate simultaneously, and the first-color light-emitting units and the second-color light-emitting units are disposed in the same layer.

A third-color material layer is prepared on a side of a second substrate.

The first substrate and the second substrate are combined such that the first-color light-emitting units, the second-color light-emitting units, and the third-color material layer are disposed between the first substrate and the second substrate.

The second substrate is removed.

Partition slots are manufactured, where the partition slots extend through at least the third-color material layer to form multiple third-color sublayers, and a third-color sublayer whose vertical projection on the first substrate does not overlap a vertical projection of a first-color light-emitting unit on the first substrate or a vertical projection of a second-color light-emitting unit on the first substrate is a third-color light-emitting unit.

According to another aspect of the present disclosure, a preparation method of a full-color LED structure is provided. The method includes the steps described below.

First-color light-emitting units and second-color light-emitting units are prepared on a side of a first substrate simultaneously, and the first-color light-emitting units and the second-color light-emitting units are disposed in the same layer.

Third-color light-emitting units are prepared on a side of a second substrate.

The first substrate and the second substrate are combined such that the first-color light-emitting units, the second-color light-emitting units, and the third-color light-emitting units are disposed between the first substrate and the second substrate, and a vertical projection of a third-color light-emitting unit on the first substrate does not overlap a vertical projection of a first-color light-emitting unit on the first substrate or a vertical projection of a second-color light-emitting unit on the first substrate.

The second substrate is removed.

The full-color LED structure provided by the technical schemes of embodiments of the present disclosure includes the first substrate, the first-color light-emitting units, the second-color light-emitting units, and the third-color light-emitting units. The first-color light-emitting units and the second-color light-emitting units are disposed on one side of the first substrate, in the same layer, and simultaneously prepared. The third-color light-emitting units are disposed on the side of the first-color light-emitting units and the second-color light-emitting units facing away from the first substrate, the vertical projection of the third-color light-emitting unit on the first substrate does not overlap the vertical projection of the first-color light-emitting unit on the first substrate or the vertical projection of the second-color light-emitting unit on the first substrate so that the first-color light-emitting units, the second-color light-emitting units, and the third-color light-emitting units can be independent of each other and light emitted by the first-color light-emitting units, light emitted by the second-color light-emitting units, and light emitted by the third-color light-emitting units do not overlap and are less shielded. Therefore, color brightness is relatively high, a full-color display can be achieved, and light emission efficiency is improved.

### BRIEF DESCRIPTION OF DRAWINGS

To illustrate technical schemes in embodiments of the present disclosure more clearly, drawings used in the description of the embodiments are briefly described below. Apparently, the drawings described below only illustrate part of the embodiments of the present disclosure, and those of ordinary skill in the art may obtain other drawings based on the drawings on the premise that no creative work is done.

FIG. 1 is a schematic diagram of a full-color LED structure according to embodiment one of the present disclosure;

FIG. 2 is a schematic diagram of another full-color LED structure according to embodiment one of the present disclosure;

FIG. 3 is an arrangement diagram of light-emitting units according to embodiment one of the present disclosure;

FIG. 4 is another arrangement diagram of light-emitting units according to embodiment one of the present disclosure;

FIG. 5 is another arrangement diagram of light-emitting units according to embodiment one of the present disclosure;

FIG. 6 is another arrangement diagram of light-emitting units according to embodiment one of the present disclosure;

FIG. 7 is another arrangement diagram of light-emitting units according to embodiment one of the present disclosure;

FIG. 8 is a schematic diagram of another full-color LED structure according to embodiment one of the present disclosure;

FIG. 9 is a flowchart of a preparation method of a full-color LED structure according to embodiment two of the present disclosure;

FIG. 10 is a schematic diagram of an intermediate structure of a full-color LED structure according to embodiment two of the present disclosure;

FIG. 11 is a schematic diagram of an intermediate structure of a full-color LED structure according to embodiment two of the present disclosure;

FIG. 12 is a schematic diagram of an intermediate structure of a full-color LED structure according to embodiment two of the present disclosure;

FIG. 13 is a schematic diagram of an intermediate structure of a full-color LED structure according to embodiment two of the present disclosure;

FIG. 14 is a detailed flowchart of step 300 in FIG. 9;

FIG. 15 is a schematic diagram of an intermediate structure of a full-color LED structure according to embodiment two of the present disclosure;

FIG. 16 is a schematic diagram of an intermediate structure of a full-color LED structure according to embodiment two of the present disclosure;

FIG. 17 is a schematic diagram of an intermediate structure of a full-color LED structure according to embodiment two of the present disclosure;

FIG. 18 is a detailed flowchart of step 310 in FIG. 14;

FIG. 19 is a schematic diagram of an intermediate structure of a full-color LED structure according to embodiment two of the present disclosure;

FIG. 20 is a schematic diagram of an intermediate structure of a full-color LED structure according to embodiment two of the present disclosure;

FIG. 21 is a schematic diagram of an intermediate structure of a full-color LED structure according to embodiment two of the present disclosure;

FIG. 22 is a schematic diagram of an intermediate structure of a full-color LED structure according to embodiment two of the present disclosure;

FIG. 23 is a schematic diagram of an intermediate structure of a full-color LED structure according to embodiment two of the present disclosure;

FIG. 24 is a schematic diagram of an intermediate structure of a full-color LED structure according to embodiment two of the present disclosure;

FIG. 25 is a schematic diagram of an intermediate structure of a full-color LED structure according to embodiment two of the present disclosure;

FIG. 26 is a flowchart of a preparation method of a full-color LED structure according to embodiment three of the present disclosure;

FIG. 27 is a schematic diagram of a full-color LED structure according to embodiment three of the present disclosure; and

FIG. 28 is a schematic diagram of a full-color LED structure according to embodiment three of the present disclosure.

### DETAILED DESCRIPTION

To make technical schemes of the present disclosure better understood by those skilled in the art, the technical schemes in embodiments of the present disclosure are described below clearly and completely in conjunction with drawings in the embodiments of the present disclosure. Apparently, the embodiments described below are part, not all, of the embodiments of the present disclosure. Based on the embodiments of the present disclosure, all other embodiments obtained by those of ordinary skill in the art on the premise that no creative work is done are within the scope of the present disclosure.

It is to be noted that terms such as “first” and “second” in the description, claims, and drawings of the present disclosure are used for distinguishing between similar objects and are not necessarily used for describing a particular order or sequence. It is to be understood that the data used in this manner is interchangeable in appropriate cases so that the embodiments of the present disclosure described herein can be implemented in an order not illustrated or described herein. In addition, the terms “including”, “having”, and any other variations thereof are intended to cover a non-exclusive inclusion. For example, a process, a method, a system, a product, or a device that includes a series of steps or units may include not only the expressly listed steps or units but also other steps or units that are not expressly listed or are inherent to the process, the method, the product, or the device.

### Embodiment One

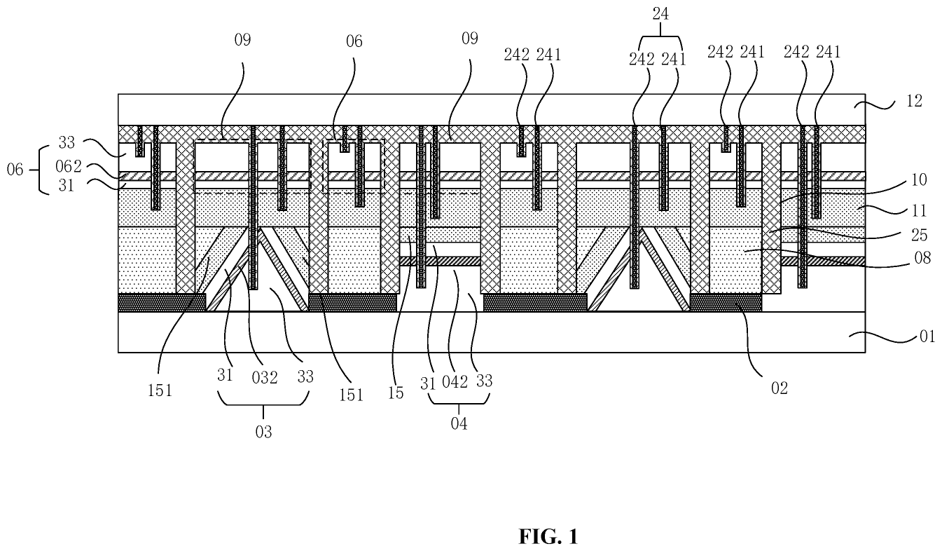

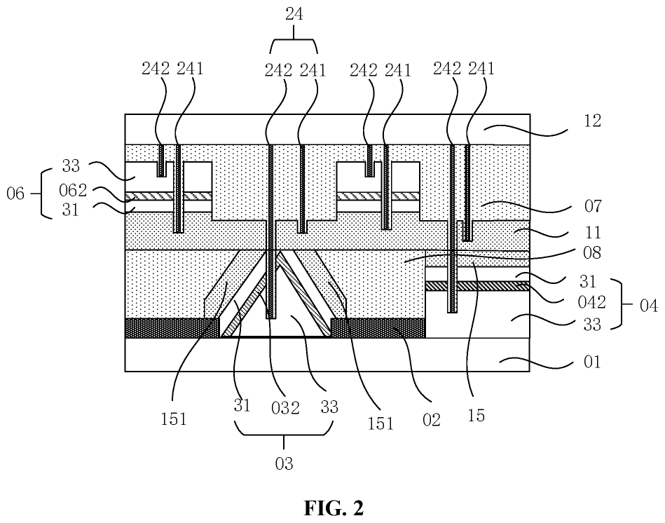

Embodiments of the present disclosure provide a full-color LED structure. FIG. 1 is a structural diagram of a full-color LED structure according to embodiment one of the present disclosure, and FIG. 2 is a structural diagram of another full-color LED structure according to embodiment one of the present disclosure. Referring to FIGS. 1 and 2, the full-color LED structure includes a first substrate 01, first-color light-emitting units 03, second-color light-emitting units 04, and third-color light-emitting units 06.

The first-color light-emitting units 03 and the second-color light-emitting units 04 are disposed on one side of the first substrate 01, and first-color light-emitting units 03 and the second-color light-emitting units 04 are disposed in the same layer and simultaneously prepared. The third-color light-emitting units 06 are disposed on a side of the first-color light-emitting units 03 and the second-color light-emitting units 04 facing away from the first substrate 01, and a vertical projection of a third-color light-emitting unit 06 on the first substrate 01 does not overlap a vertical projection of a first-color light-emitting unit 03 on the first substrate 01 or a vertical projection of a second-color light-emitting unit 04 on the first substrate 01.

The material of the first substrate 01 may be silicon, sapphire, and the like. In an embodiment, the material of the first substrate 01 may be transparent. The three-dimensional shape of the first-color light-emitting unit 03 may be a hexagonal pyramid, a hexagonal frustum, or a tetrahedron. The first-color light-emitting units 03 and the second-color light-emitting units 04 may be simultaneously grown on one side of the first substrate 01. The first-color light-emitting units 03 and the second-color light-emitting units 04 may be simultaneously prepared in a selective epitaxial growth manner by controlling the duty cycle of a window. Thus, process steps can be simplified.

As shown in FIG. 1, if the shape of the first-color light-emitting unit 03 is a hexagonal pyramid and the shape of the second-color light-emitting unit 04 is a tetrahedron, the height of the first-color light-emitting unit 03 is greater than the height of the second-color light-emitting unit 04, that is, the first-color light-emitting units 03 and the second-color light-emitting units 04 are in the same layer but have different heights. If the shape of the first-color light-emitting unit 03 and the shape of the second-color light-emitting unit 04 are both tetrahedrons, the height of the first-color light-emitting unit 03 is the same as the height of the second-color light-emitting unit 04, that is, the first-color light-emitting units 03 and the second-color light-emitting units 04 are in the same layer and have the same height. The vertical projection of the third-color light-emitting unit 06 on the first substrate 01 does not overlap the vertical projection of the first-color light-emitting unit 03 on the first substrate 01 or the vertical projection of the second-color light-emitting unit 04 on the first substrate 01 so that light emitted by the first-color light-emitting units 03, light emitted by the second-color light-emitting units 04, and light emitted by the third-color light-emitting units 06 do not overlap each other and are less shielded. Therefore, a full-color display can be achieved, and light emission efficiency is improved.

In an embodiment, referring to FIGS. 1 and 2, the full-color LED structure further includes a mask layer 02 disposed between the first-color light-emitting units 03 and the second-color light-emitting units 04, the mask layer 02 includes multiple first mask holes and multiple second mask holes, the first-color light-emitting units 03 are correspondingly disposed in the first mask holes, and the second-color light-emitting units 04 are correspondingly disposed in the second mask holes. The dimension of the first mask hole is larger than the dimension of the second mask hole.

The material of the mask layer 02 may be silicon dioxide (SiO₂) or silicon nitride (SiNₓ). The first mask hole and the second mask hole may each have any shape such as a circle, a square, or a hexagon. One first-color light-emitting unit 03 is correspondingly grown in each first mask hole, and one second-color light-emitting unit 04 is correspondingly grown in each second mask hole. Under the same preparation condition, the second-color light-emitting unit 04 grown in the relatively small second mask hole may be in the shape of a tetrahedron and emit light through a horizontal plane, while the first-color light-emitting unit 03 grown in the relatively large first mask hole may be in the shape of a hexagonal pyramid and emit light through an inclined surface. In an embodiment, the dimension of the first mask hole may be equal to the dimension of the second mask hole. In an embodiment, the dimension of the first mask hole may be smaller than the dimension of the second mask hole.

In an embodiment, the first mask hole has an aperture of less than 20 μm.

The aperture of the first mask hole is less than 20 μm by pattern etching so that the first-color light-emitting unit 03 grown in the first mask hole is in the shape of a hexagonal pyramid.

In an embodiment, in a direction perpendicular to the first substrate 01, a section of the first-color light-emitting unit 03 is triangular or trapezoidal. In an embodiment, the included angle between the inclined surface of the first-color light-emitting unit 03 and the first substrate 01 is greater than 50°.

In an embodiment, referring to FIGS. 1 and 2, the full-color LED structure further includes a first passivation layer 08 disposed on the side of the mask layer 02 facing away from the first substrate 01 and disposed on the upper surface of the mask layer 02. The first passivation layer 08 performs the function of isolation and insulation between the first color light-emitting units 03 and the second color light-emitting units 04.

In an embodiment, the first-color light-emitting unit 03 is a blue LED unit, the second-color light-emitting unit 04 is a green LED unit, and the third-color light-emitting unit 06 is a red LED unit. In an embodiment, the first substrate 01 is a silicon substrate, and GaN-based blue LED units and GaN-based green LED units are manufactured on the silicon substrate, the second substrate 05 is a GaAs substrate, and InP-based red LED units are manufactured on the GaAs substrate. In an embodiment, the silicon substrate has a dimension of 8 inches or 12 inches, and the GaAs substrate has a dimension of 6 inches. In an embodiment, each of the first substrate 01 and the second substrate 05 is a silicon substrate, the blue LED units, the green LED units, and the red LED units are all made of a GaN-based material, and each of the first substrate 01 and the second substrate 05 may have a dimension of 8 inches or 12 inches. The dimension of the first substrate 01 and the dimension of the second substrate 05 remain uniform for the ease of the alignment of a bonding process.

The blue LED units, the green LED units, and the red LED units can achieve the colorization of the LED structure and the full-color display. In an embodiment, referring to FIGS. 1 and 2, the first-color light-emitting unit 03 includes a first semiconductor layer 31, a first light-emitting layer 032, and a second semiconductor layer 33 which are sequentially stacked, and a surface of the first light-emitting layer 032 facing away from the first substrate 01 is an inclined surface. The second-color light-emitting unit 04 includes a first semiconductor layer 31, a second light-emitting layer 042, and a second semiconductor layer 33 which are sequentially stacked, and a surface of the second light-emitting layer 042 facing away from the first substrate 01 is parallel to the first substrate 01.

The first-color light-emitting unit 03 is the blue LED unit, and the three-dimensional shape of the first-color light-emitting unit 03 is a hexagonal pyramid or a hexagonal frustum. Therefore, the surface of the first light-emitting layer 032 facing away from the first substrate 01 is the inclined surface.

Similarly, the third-color light-emitting unit 06 includes a first semiconductor layer 31, a third light-emitting layer 062, and a second semiconductor layer 33 which are sequentially stacked. The conductivity types of the first semiconductor layer 31 and the second semiconductor layer 33 are different, and one of the conductivity types of the first semiconductor layer 31 and the second semiconductor layer 33 is an N-type doped semiconductor layer and the other is a P-type doped semiconductor layer. Each of the material of the first semiconductor layer 31 and the material of the second semiconductor layer 33 includes one or more of AlN, GaN, AlGaN, or InGaN. It is to be noted that referring to FIG. 1, the first semiconductor layer 31 of the first-color light-emitting unit 03 faces the first semiconductor layer 31 of the third-color light-emitting unit 06.

In an embodiment, referring to FIGS. 1 and 2, the full-color LED structure further includes an inclined conductive layer 151, and the inclined conductive layer 151 is disposed on the side of the first semiconductor layer 31 of the first-color light-emitting unit 03 facing away from the first light-emitting layer 032.

The material of the inclined conductive layer 151 may be an indium tin oxide film. The inclined conductive layer 151 is disposed on the side of the first semiconductor layer 31 of the first-color light-emitting unit 03 facing away from the first light-emitting layer 032 so that the current of the first semiconductor layer 31 can be distributed more evenly and electrons or holes in the first semiconductor layer 31 can evenly enter the first light-emitting layer 032. In an embodiment, the material of a first sublayer 15 on the second-color light-emitting unit 04 is an indium tin oxide film. The first sublayer 15 is a planar structure parallel to the first substrate 01, and the first sublayer 15 and the inclined conductive layer 151 are simultaneously manufactured.

In an embodiment, referring to FIGS. 1 and 2, the full-color LED structure further includes a transparent conductive layer 11 disposed on the side of the third-color light-emitting units 06 facing the first-color light-emitting unit 03 and the second-color light-emitting unit 04.

The material of the transparent conductive layer 11 may be an indium tin oxide film with good conductivity and visible light transmittance. The transparent conductive layer 11 in FIGS. 1 and 2 is disposed between the third-color light-emitting units 06 and the first-color light-emitting units 03 as well as the second-color light-emitting units 04, and the transparent conductive layer 11 covers the first passivation layer 08, the inclined conductive layer 151, the first-color light-emitting units 03, the first sublayer 15 on the second-color light-emitting units 04, and the surface of the third-color light-emitting units 06. It is to be noted that the transparent conductive layer 11 is disposed on the side of the third-color light-emitting unit 06 facing the first-color light-emitting unit 03 and the second-color light-emitting unit 04 and is electrically connected to the first semiconductor layer 31 of the first-color light-emitting unit 03, the first semiconductor layer 31 of the second-color light-emitting unit 04, and the first semiconductor layer 31 of the third-color light-emitting unit 06. Therefore, the transparent conductive layer 11 may be used as a common electrode of the preceding three types of light-emitting units so that a region where the contact points between the electrodes and the first semiconductor layers 31 are manufactured is enlarged, thereby improving the manufacturing yield of the contact between the electrodes and the first semiconductor layers 31.

In an embodiment, referring to FIGS. 1 and 2, the full-color LED structure further includes a drive unit layer 12 disposed on the side of the third-color light-emitting units 06 facing away from the first substrate 01, the drive unit layer 12 includes multiple drive units and multiple first electrodes 241, each first electrode 241 is electrically connected to the transparent conductive layer 11 and a respective light-emitting unit, and each drive unit provides an electrical signal for a respective light-emitting unit through a respective first electrode 541 and the transparent conductive layer 11.

In an embodiment, the full-color LED structure further includes second electrodes 242. The first electrodes 241 provide the same electrical signal for each light-emitting unit, and the same electrical signal is equivalent to a common electrical signal. The second electrodes 242 provide the same electrical signal or different electrical signals for light-emitting units, and the electrical signal provided by the second electrodes 242 is equivalent to a driving electrical signal. Therefore, the multiple drive units of the drive unit layer independently control the first-color light-emitting units 03, the second-color light-emitting units 04, and the third-color light-emitting units 06 separately. After a voltage is applied, the light-emitting units do not affect each other. Therefore, the full-color display can be achieved and the light emission efficiency is improved.

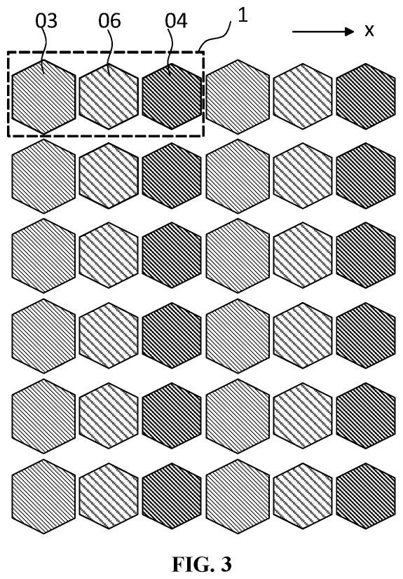

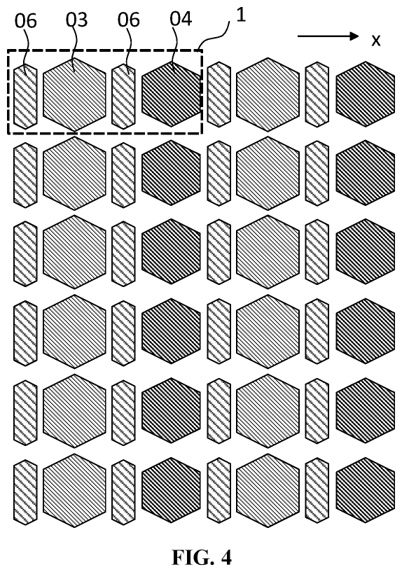

In an embodiment, the full-color LED structure includes multiple light-emitting unit groups 1. FIG. 3 is an arrangement diagram of light-emitting units according to embodiment one of the present disclosure, referring to FIG. 3, the multiple light-emitting unit groups 1 are arranged in an array, and each light-emitting unit group 1 includes one first-color light-emitting unit 03, one third-color light-emitting unit 06, and one second-color light-emitting unit 04. Alternatively, FIG. 4 is another arrangement diagram of light-emitting units according to embodiment one of the present disclosure, and referring to FIG. 4, each light-emitting unit group 1 includes one first-color light-emitting unit 03, two third-color light-emitting units 06, and one second-color light-emitting unit 04.

FIG. 3 and FIG. 4 show examples of two different light-emitting unit groups 1. Different light-emitting unit groups 1 may be disposed according to user requirements so that the full-color display is achieved. Each light-emitting unit group 1 in FIG. 3 includes one first-color light-emitting unit 03, one third-color light-emitting unit 06, and one second-color light-emitting unit 04, and light-emitting units in each light-emitting unit group 1 are arranged in a sequence of the first-color light-emitting unit 03, the third-color light-emitting unit 06, and the second-color light-emitting unit 04 along a first direction x. Each light-emitting unit group 1 in FIG. 4 includes one first-color light-emitting unit 03, two third-color light-emitting units 06, and one second-color light-emitting unit 04, and light-emitting units in each light-emitting unit group 1 are arranged in a sequence of the third-color light-emitting unit 06, the first-color light-emitting unit 03, the third-color light-emitting unit 06, and the second-color light-emitting unit 04 along the first direction x. It is to be noted that FIGS. 3 and 4 illustrate only hexagonal light-emitting units but the section shape of each light-emitting unit is not limited, and the section area of each light-emitting unit is not limited by figure dimensions illustrated in FIGS. 3 and 4.

In an embodiment, FIG. 5 is another arrangement diagram of light-emitting units according to embodiment one of the present disclosure. FIG. 3 illustrates that the included angle between the arrangement direction of light-emitting units of different colors and the arrangement direction of light-emitting units of the same color is 90°. FIG. 5 illustrates that the included angle between the arrangement direction of light-emitting units of different colors and the arrangement direction of light-emitting units of the same color is not 90°.

In an embodiment, FIG. 6 is another arrangement diagram of light-emitting units according to embodiment one of the present disclosure, where two light-emitting unit groups 1 constitute a delta arrangement.

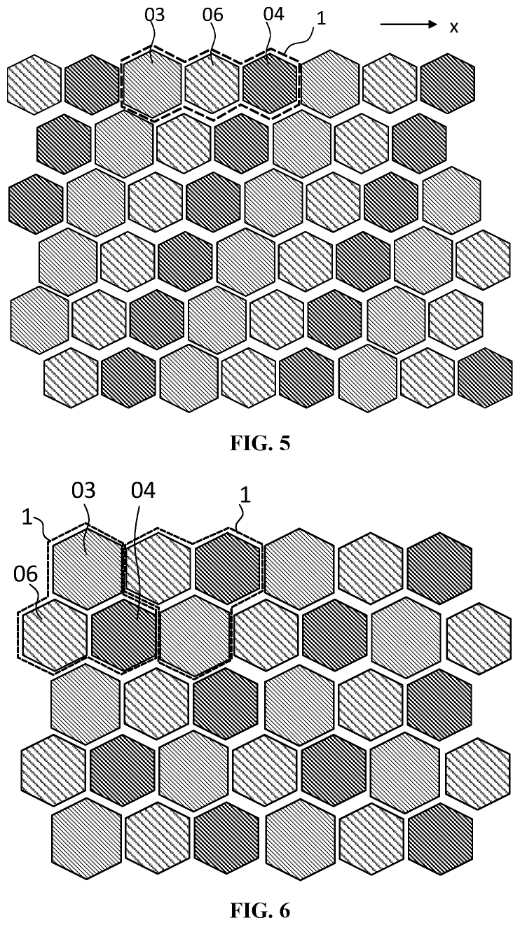

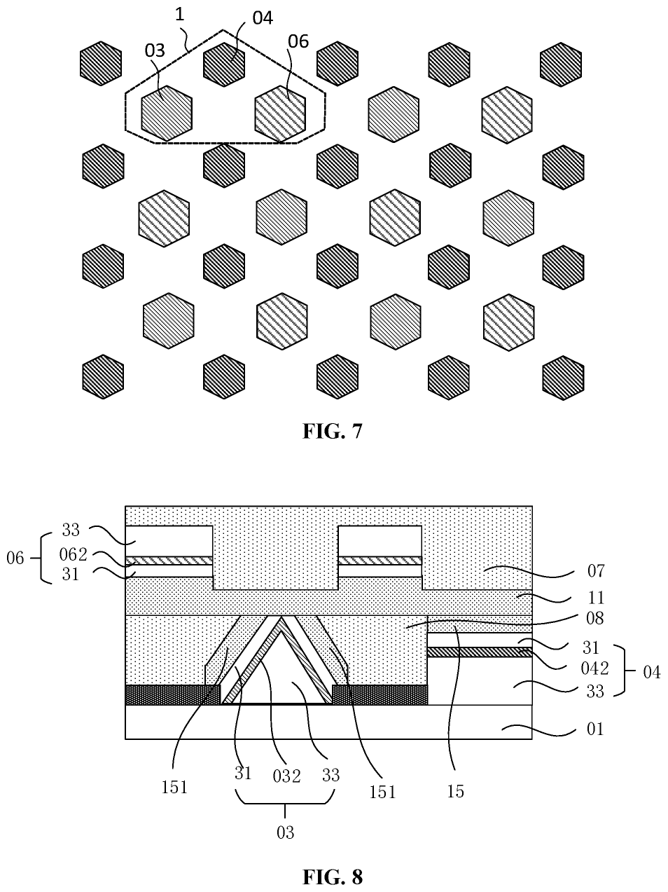

In an embodiment, FIG. 7 is another arrangement diagram of light-emitting units according to embodiment one of the present disclosure, where a light-emitting unit group 1 constitutes a diamond-shaped arrangement.

In an embodiment, FIG. 8 is a structural diagram of another full-color LED structure according to embodiment one of the present disclosure, and referring to FIG. 8, a second passivation layer 07 is disposed between adjacent third-color light-emitting units 06. Alternatively, referring to FIG. 1, a third-color material layer 09 is disposed between adjacent third-color light-emitting units 06, and the third-color material layer 09 and the third-color light-emitting unit 06 are partitioned by a partition slot 10, where the material of the third-color material layer 09 is the same as the material of the third-color light-emitting unit 06.

Referring to FIG. 8, in the preparation process of the third-color light-emitting units 06, the third-color material layer 09 may be prepared on the second substrate, and the corresponding third-color material layer 09 on the first-color light-emitting units 03 and the corresponding third-color material layer 09 on the second-color light-emitting units 04 are removed, so as to avoid the case where the third-color material layer 09 above the first-color light-emitting units 03 and the second-color light-emitting units 04 are excited to emit light and a light emission effect is effected because the first-color light-emitting units 03 and the second-color light-emitting units 04 emit light. The remaining third-color material layer 09 forms the third-color light-emitting units 06, the second passivation layer 07 is filled between adjacent third-color light-emitting units 06, and the second passivation layer 07 between the third-color light-emitting units 06 corresponds to the second-color light-emitting unit 04 or the first-color light-emitting unit 03. Alternatively, referring to FIG. 1, the third-color material layer 09 may be prepared on the second substrate, the third-color material layer 09 corresponds to the first-color light-emitting unit 03 and the second-color light-emitting unit 04, the region which does not correspond to the first-color light-emitting unit 03 or the second-color light-emitting unit 04 is the third-color light-emitting unit 06, and the third-color material layer 09 corresponding to the first-color light-emitting unit 03 and the second-color light-emitting unit 04 is not removed so that the manufacturing process is simplified. Moreover, the third-color material layer 09 is partitioned from the third-color light-emitting units 06 by the partition slots 10 so that the light emitted from the first-color light-emitting units 03 is not shielded by the second-color light-emitting units 04 or the third-color light-emitting units 06, thereby improving the light emission efficiency of the first-color light-emitting units 03.

### Embodiment Two

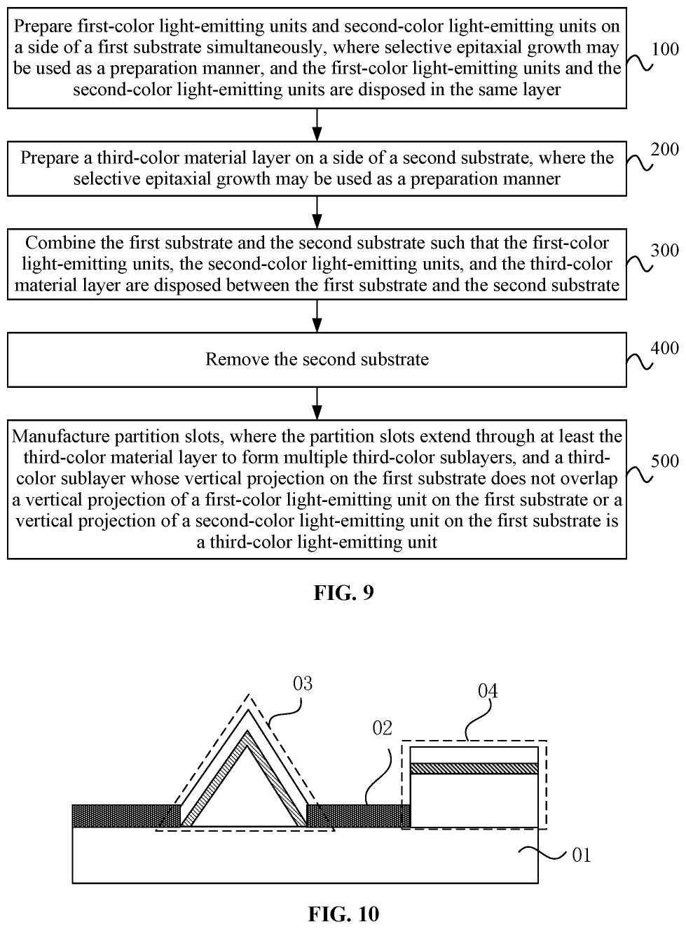

Based on the preceding embodiment, an embodiment of the present disclosure provides a preparation method of a full-color LED structure. FIG. 9 is a flowchart of a preparation method of a full-color LED structure according to embodiment two of the present disclosure, and FIGS. 10 to 13 are schematic diagrams of intermediate structures of a full-color LED structure according to embodiment two of the present disclosure. Referring to FIG. 9, the preparation method includes the steps below.

In step 100, referring to FIG. 10, first-color light-emitting units 03 and second-color light-emitting units 04 are prepared on one side of a first substrate 01 simultaneously, a selective epitaxial growth manner may be used for preparation, and the first-color light-emitting units 03 and the second-color light-emitting units 04 are disposed in the same layer.

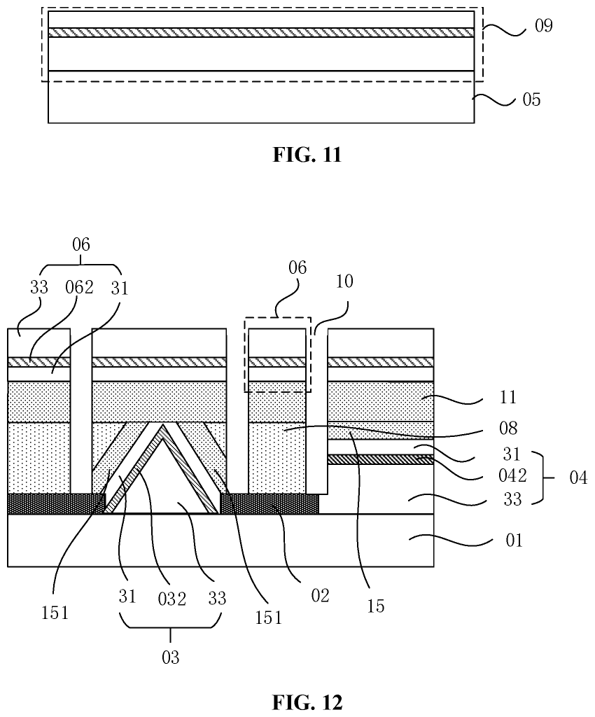

In step 200, referring to FIG. 11, a third-color material layer 09 is prepared on a side of a second substrate 05, and the selective epitaxial growth manner may be used for preparation.

In step 300, the first substrate and the second substrate are combined such that the first-color light-emitting units, the second-color light-emitting units, and the third-color material layer are disposed between the first substrate and the second substrate.

In step 400, the second substrate is removed.

In step 500, partition slots are manufactured, the partition slots extend through at least the third-color material layer to form multiple third-color sublayers, and a third-color sublayer whose vertical projection on the first substrate does not overlap a vertical projection of a first-color light-emitting unit on the first substrate or a vertical projection of a second-color light-emitting unit on the first substrate is a third-color light-emitting unit.

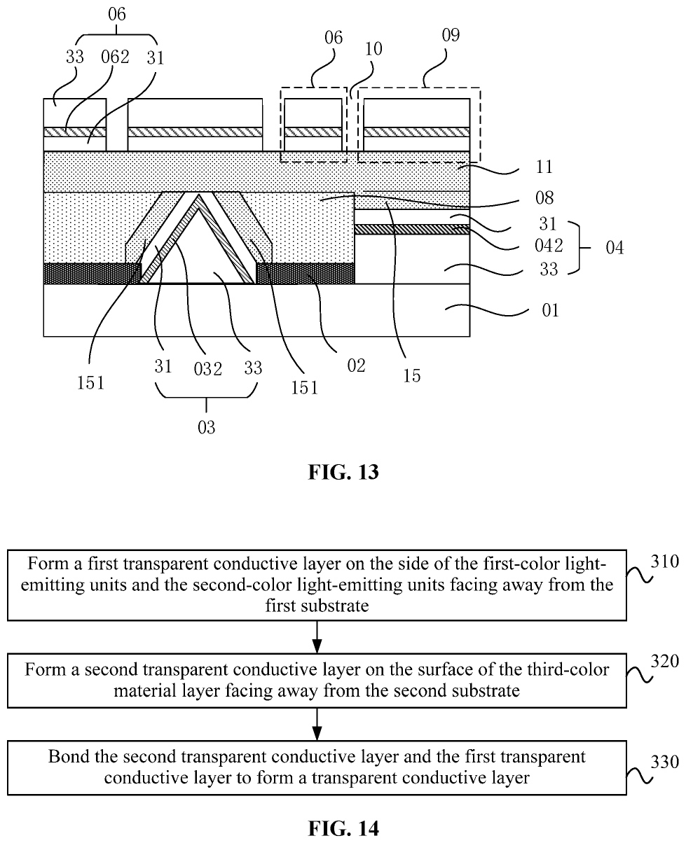

Referring to FIG. 12, the partition slot 10 extends through the third-color material layer, a transparent conductive layer 11, and a first passivation layer 08, the partition slot 10 is manufactured on the side of the third-color material layer 09 facing away from the first substrate 01, and the partition slot 10 is disposed between the first-color light-emitting unit 03 and the second-color light-emitting unit 04. Referring to FIG. 13, the partition slot 10 extends through the third-color material layer 09, and the partition slot 10 is used for partitioning the third-color material layer 09 into the multiple third-color sublayers, a third-color sublayer whose vertical projection on the first substrate 01 does not overlap the vertical projection of the first-color light-emitting unit on the first substrate 01 or the vertical projection of the second-color light-emitting unit on the first substrate 01 is the third-color light-emitting unit.

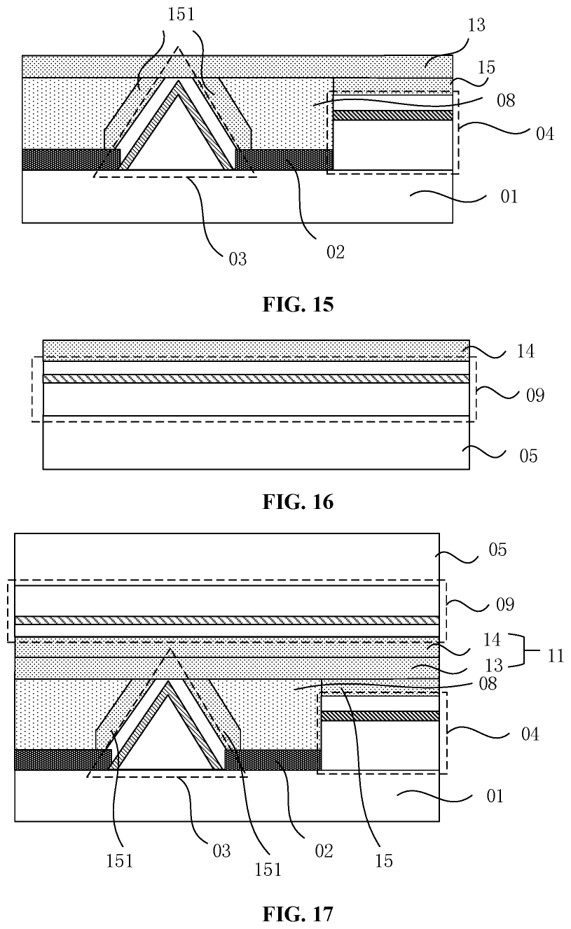

In an embodiment, FIG. 14 is a detailed flowchart of step 300 in FIG. 9, and FIGS. 15 to 17 are schematic diagrams of intermediate structures of a full-color LED structure according to embodiment two of the present disclosure. Step 300 in which the first substrate 01 and the second substrate 05 are combined includes the steps described below.

In step 310, referring to FIG. 15, a first transparent conductive layer 13 is formed on the side of the first-color light-emitting units 03 and the second-color light-emitting units 04 facing away from the first substrate 01.

In step 320, referring to FIG. 16, a second transparent conductive layer 14 is formed on the surface of the third-color material layer 09 facing away from the second substrate 05.

In step 330, referring to FIG. 17, the second transparent conductive layer 14 and the first transparent conductive layer 13 are bonded so that the transparent conductive layer 11 is formed.

Each of the material of the first transparent conductive layer 13 and the material of the second transparent conductive layer 14 is an indium tin oxide film. The indium tin oxide film may be formed through deposition. An intermolecular force exists between these two indium tin oxide films. Therefore, without the use of other bonding materials, the second transparent conductive layer 14 and the first transparent conductive layer 13 can be directly bonded to form the transparent conductive layer 11.

In an embodiment, referring to FIG. 17, the step in which the first-color light-emitting units 03 and the second-color light-emitting units 04 are prepared on the side of the first substrate 01 simultaneously, and the first-color light-emitting units 03 and the second-color light-emitting units 04 are disposed in the same layer further includes the steps described below.

A mask layer 02 is prepared on the first substrate 01, the mask layer 02 includes multiple first mask holes and multiple second mask holes, and the dimension of a first mask hole is larger than the dimension of a second mask hole.

The first mask holes and the second mask holes may be prepared through patterned etching, and then the first-color light-emitting units 03 and the second-color light-emitting units 04 are simultaneously prepared the first mask holes and the second mask holes in the selective epitaxial growth manner. Thus, the process for preparing light-emitting units of different colors is simplified. The first-color light-emitting unit 03 is correspondingly formed in a respective first mask hole, and the second-color light-emitting unit 04 is correspondingly formed in a respective second mask hole.

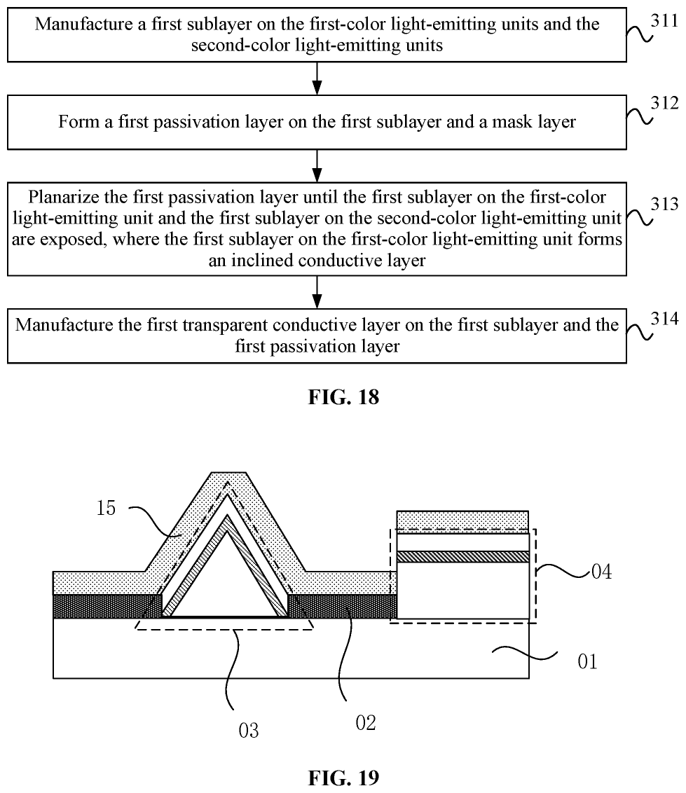

In an embodiment, the first-color light-emitting unit 03 is a blue LED unit and the surface of the first-color light-emitting unit 03 facing away from the first substrate 01 is an inclined surface. FIG. 18 is a detailed flowchart of step 310 in FIG. 14, and FIGS. 19 to 23 are schematic diagrams of intermediate structures of a full-color LED structure according to embodiment two of the present disclosure. The preparation method further includes the steps below.

In step 311, a first sublayer is manufactured on the first-color light-emitting units and the second-color light-emitting units.

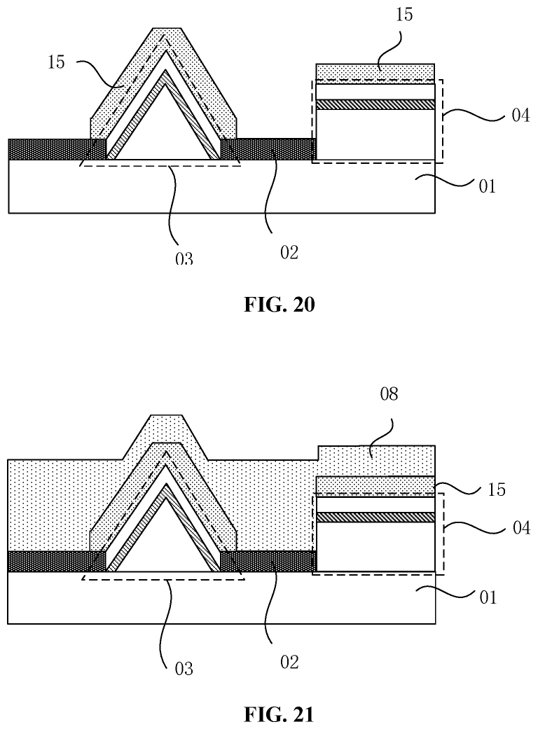

The material of the first sublayer 15 is an indium tin oxide film. Referring to FIG. 19, the first sublayer 15 is deposited on the first-color light-emitting unit 03 and the second-color light-emitting unit 04 as a whole layer. Referring to FIG. 20, the first sublayer 15 on the mask layer 02 is removed so that the first-color light-emitting unit 03 and the second-color light-emitting unit 04 are prevented from interfering with each other after being energized.

In step 312, referring to FIG. 21, a first passivation layer 08 is formed on the first sublayer 15 and the mask layer 02.

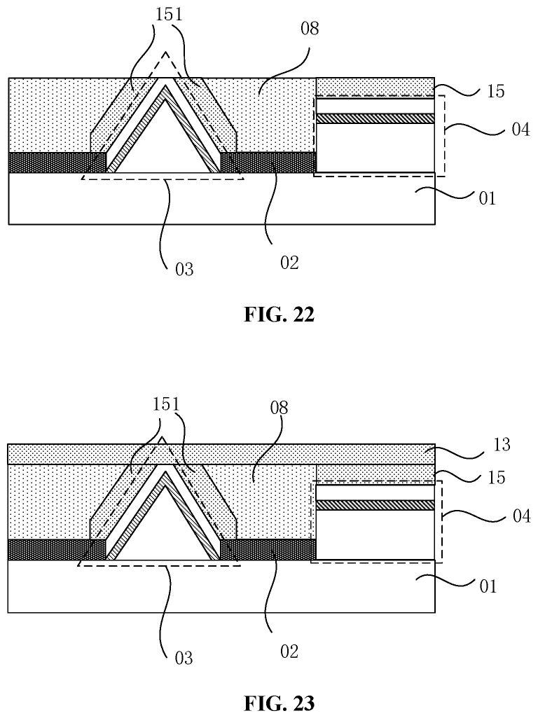

In step 313, referring to FIG. 22, the first passivation layer 08 is planarized until the first sublayer 15 on the first-color light-emitting unit 03 and the first sublayer 15 on the second-color light-emitting unit 04 are exposed, and the first sublayer 15 on the first-color light-emitting unit 03 forms an inclined conductive layer 151. The planarization may refer to chemical mechanical polishing (CMP).

In step 314, referring to FIG. 23, a first transparent conductive layer 13 is manufactured on the first sublayer 15 and the first passivation layer 08, where the first transparent conductive layer 13 is deposited and manufactured as a whole layer.

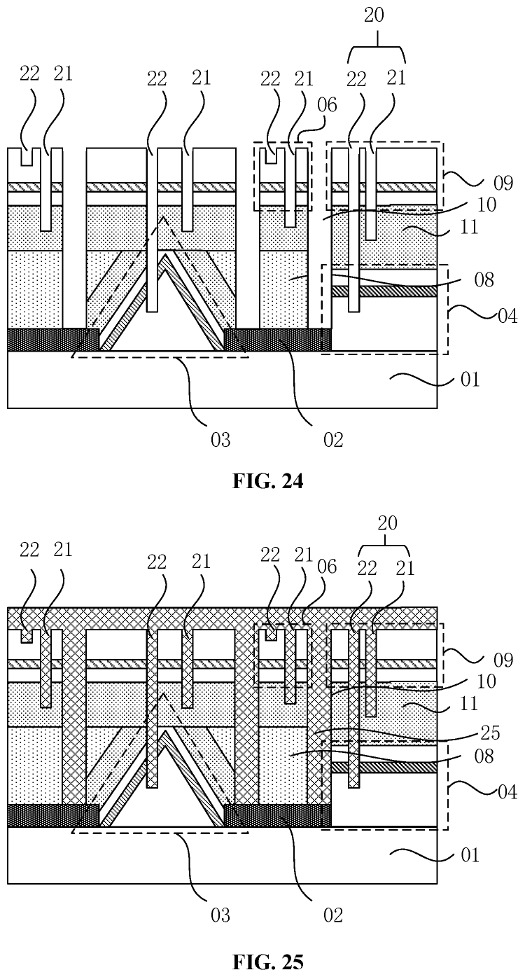

In an embodiment, FIGS. 24 and 25 are schematic diagrams of intermediate structures of a full-color LED structure according to embodiment two of the present disclosure. Referring to FIG. 24, when the partition slots 10 are manufactured, the method further includes manufacturing electrode vias 20 corresponding to the light-emitting units. Referring to FIG. 25, when the partition slots 10 are manufactured, the method further includes forming a fourth passivation layer 25 and forming a drive unit layer 12 on the side of the third-color light-emitting units 06 facing away from the first substrate 01. The fourth passivation layer 25 fills the partition slots 10 and the electrode vias 20, and the fourth passivation layer 25 covers the surface of each third-color light-emitting unit 06 facing away from the first substrate 01. Referring to FIG. 1, an electrode structure 24 is formed in the fourth passivation layer 25 of the electrode vias 20, that is, the fourth passivation layer 25 remains on the sidewalls of the electrode vias 20 and the electrode structure 24 is manufactured in the holes formed through etching. The electrode structure 24 includes multiple first electrodes 241 and each first electrode 241 is electrically connected to the transparent conductive layer 11 and a respective light-emitting unit. The drive unit layer 12 includes multiple drive units, and each drive unit provides an electrical signal for a respective light-emitting unit through a respective first electrode 241 and the transparent conductive layer 11.

The partition slots 10 and the electrode vias 20 may be formed simultaneously through etching, and the planarization is performed after the fourth passivation layer 25 is manufactured. Referring to FIG. 24, the electrode vias 20 include a first via 21 and a second via 22, where the first via 21 extends to the transparent conductive layer 11, and the second via 22 extends to the second semiconductor layer of each light-emitting unit.

The drive unit layer 12 is formed on the side of the third-color light-emitting units 06 facing away from the first substrate 01, and each light-emitting unit is electrically connected to the drive unit through the electrode structure 24. For example, referring to FIGS. 24 and 1, the first semiconductor layer 31 of each light-emitting unit is electrically connected to the drive unit through the transparent conductive layer 11 and the first electrode 241, the first electrode 241 provides the common electrical signal, the second semiconductor layer 33 of each light-emitting unit is electrically connected to the drive unit through the second electrode 242, and the second electrode 242 provides the driving electrical signal.

In an embodiment, the first via 21 extends to a respective first semiconductor layer 31, so the first semiconductor layer 31 is electrically connected to the drive unit directly through the first electrode 241.

According to the preparation method of the full-color LED structure provided by the technical schemes of the embodiment of the present disclosure, a full-color display can be achieved, and light emission efficiency is improved.

### Embodiment Three

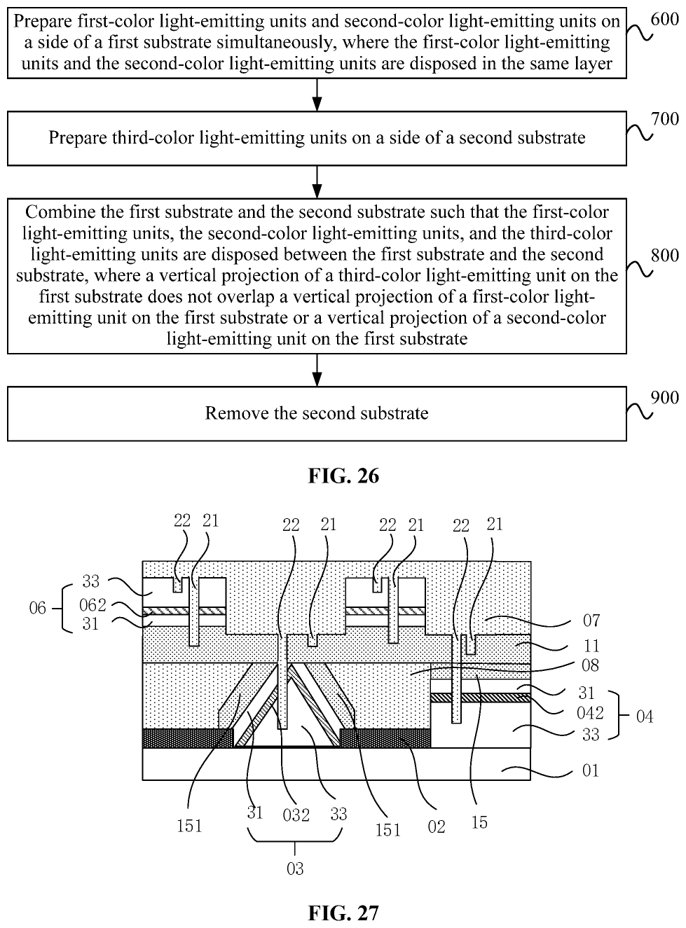

Based on the preceding embodiment, an embodiment of the present disclosure further provides a preparation method of a full-color LED structure. FIG. 26 is a flowchart of another preparation method of a full-color LED structure according to embodiment three of the present disclosure. The preparation method includes the steps below.

In step 600, first-color light-emitting units and second-color light-emitting units are prepared on a side of a first substrate simultaneously, and the first-color light-emitting units and the second-color light-emitting units are disposed in the same layer.

In step 700, third-color light-emitting units are prepared on a side of a second substrate.

In step 800, the first substrate and the second substrate are combined such that the first-color light-emitting units, the second-color light-emitting units, and the third-color light-emitting units are disposed between the first substrate and the second substrate, and a vertical projection of a third-color light-emitting unit on the first substrate does not overlap a vertical projection of a first-color light-emitting unit on the first substrate or a vertical projection of a second-color light-emitting unit on the first substrate.

In step 900, the second substrate is removed.

Compared with the full-color LED structure provided by embodiment two, the full-color LED structure of embodiment three includes no third-color material layer between adjacent third-color light-emitting units. The unitized third-color light-emitting units 06 are manufactured first, and the first substrate and the second substrate are combined and aligned so that the third-color light-emitting unit 06 is disposed between the first-color light-emitting unit 03 and the second-color light-emitting unit 04.

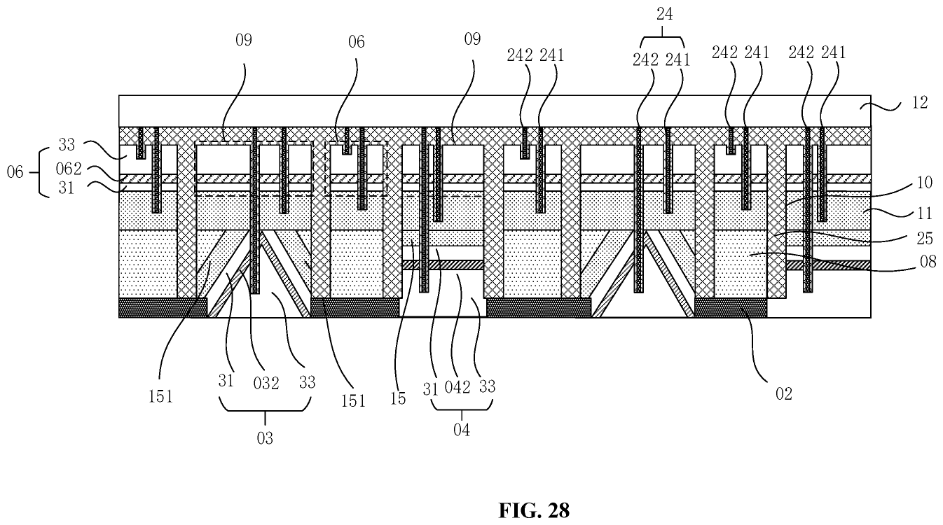

FIG. 27 is a schematic diagram of a full-color LED structure according to embodiment three of the present disclosure. Referring to FIGS. 27 and 2, after the second substrate is removed, the method further includes the following: First vias 21 extending to the transparent conductive layer 11 and second vias 22 extending to the second semiconductor layer of each light-emitting unit are formed; a second passivation layer 07 is deposited as a whole layer to fill the first vias 21 and the second vias 22 by the second passivation layer 07; along a direction perpendicular to the plane where the first substrate 01 is located, the second passivation layer 07 extending through the first vias 21 and the second vias 22 is etched; and the electrode structure 24 is manufactured in holes which are formed through etching.

A drive unit layer 12 is formed on the side of the third-color light-emitting units 06 facing away from the first substrate 01, where the drive unit layer 12 includes multiple drive units, and the drive units are electrically connected to the light-emitting units in one-to-one correspondence through the electrode structure 24. The drive unit is configured to drive a respective light-emitting unit to emit light.

In the preparation method provided by the embodiment of the present disclosure, an inclined conductive layer 151, a first sublayer 15, the transparent conductive layer 11, a mask layer 02, and a first passivation layer 08 are prepared by the preparation method same as embodiment two. According to the preparation method of the full-color LED structure provided by the technical schemes of the embodiments of the present disclosure, a full-color display can be achieved, and light emission efficiency is improved.

In some embodiments, FIG. 28 is a schematic diagram of a full-color LED structure according to embodiment three of the present disclosure. Referring to FIGS. 28 and 1, the full-color LED structure of embodiment one is used as an example, the first substrate 01 is removed, and the light emission direction of each light-emitting unit is a direction facing away from the drive unit layer 12.

It is to be understood that various forms of processes shown above may be adopted with steps reordered, added, or deleted. For example, the steps described in the present disclosure may be performed in parallel, sequentially, or in different sequences, as long as the desired results of the technical schemes of the present disclosure can be achieved, and no limitation is imposed herein.

What is claimed is:

1. A full-color light-emitting diode (LED) structure, comprising:
a first substrate;
first-color light-emitting units and second-color light-emitting units, wherein the first-color light-emitting units and second-color light-emitting units are disposed on a side of the first substrate, and the first-color light-emitting units and second-color light-emitting units are disposed in the same layer and simultaneously prepared; and
third-color light-emitting units disposed on a side of the first-color light-emitting units and the second-color light-emitting units facing away from the first substrate, wherein a vertical projection of a third-color light-emitting unit among the third-color light-emitting units on the first substrate does not overlap a vertical projection of a first-color light-emitting unit among the first-color light-emitting units on the first substrate or a vertical projection of a second-color light-emitting unit among the second-color light-emitting units on the first substrate.

2. The full-color LED structure according to claim 1, further comprising: a mask layer disposed between the first-color light-emitting units and the second-color light-emitting units,
wherein the mask layer comprises a plurality of first mask holes and a plurality of second mask holes, each of the first-color light-emitting units is correspondingly disposed in a respective first mask hole among the plurality of first mask holes, and each of the second-color light-emitting units is correspondingly disposed in a respective second mask hole among the plurality of second mask holes;
wherein a dimension of the plurality of first mask holes is larger than a dimension of the plurality of second mask holes.

3. The full-color LED structure according to claim 2, wherein each of the plurality of first mask holes has an aperture less than 20 μm.

4. The full-color LED structure according to claim 2, further comprising: a first passivation layer disposed on a side of the mask layer facing away from the first substrate, wherein the first passivation layer is disposed on an upper surface of the mask layer.

5. The full-color LED structure according to claim 1, wherein each of the first-color light-emitting units is a blue LED unit, each of the second-color light-emitting units is a green LED unit, and each of the third-color light-emitting units is a red LED unit.

6. The full-color LED structure according to claim 5, wherein a first-color light-emitting unit of the first-color light-emitting units comprises a first semiconductor layer, a first light-emitting layer, and a second semiconductor layer which are sequentially stacked, and a surface of the first light-emitting layer facing away from the first substrate is an inclined surface; and
a second-color light-emitting unit of the second-color light-emitting units comprises a first semiconductor layer, a second light-emitting layer, and a second semiconductor layer which are sequentially stacked, and a surface of the second light-emitting layer facing away from the first substrate is parallel to the first substrate.

7. The full-color LED structure according to claim 6, further comprising: an inclined conductive layer, wherein the inclined conductive layer is disposed on a side of the first semiconductor layer of the first-color light-emitting unit facing away from the first light-emitting layer.

8. The full-color LED structure according to claim 1, further comprising: a transparent conductive layer, wherein the transparent conductive layer is disposed on a side of the third-color light-emitting units facing the first-color light-emitting units and the second-color light-emitting units.

9. The full-color LED structure according to claim 8, further comprising: a drive unit layer, and a plurality of first electrodes,
wherein the drive unit layer is disposed on a side of the third-color light-emitting units facing away from the first substrate, and the drive unit layer comprises a plurality of drive units; and
each of the plurality of first electrodes is electrically connected to the transparent conductive layer and each light-emitting unit among the first-color light-emitting units, the second-color light-emitting units, and the third-color light-emitting units, and each of the plurality of drive units provides an electrical signal through the transparent conductive layer and a respective first electrode among the plurality of first electrodes for each light-emitting unit among the first-color light-emitting units, the second-color light-emitting units, and the third-color light-emitting units.

10. The full-color LED structure according to claim 1, comprising: a plurality of light-emitting unit groups arranged in an array,
wherein each of the plurality of light-emitting unit groups comprises one of the first-color light-emitting units, one of the third-color light-emitting units, and one of the second-color light-emitting units; or
each of the plurality of light-emitting unit groups comprises one of the first-color light-emitting units, two of the third-color light-emitting units, and one of the second-color light-emitting units.

11. The full-color LED structure according to claim 1, wherein a second passivation layer is disposed between adjacent third-color light-emitting units among the third-color light-emitting units; or
a third-color material layer is disposed between adjacent third-color light-emitting units among the third-color light-emitting units, and the third-color material layer and the third-color light-emitting units are partitioned by partition slots, wherein a material of the third-color material layer is the same as a material of the third-color light-emitting units.

12. A preparation method of a full-color light-emitting diode (LED) structure, comprising:
preparing first-color light-emitting units and second-color light-emitting units on a side of a first substrate simultaneously, and disposing the first-color light-emitting units and the second-color light-emitting units in a same layer;
preparing a third-color material layer on a side of a second substrate;
combining the first substrate and the second substrate such that the first-color light-emitting units, the second-color light-emitting units, and the third-color material layer are disposed between the first substrate and the second substrate;
removing the second substrate; and
manufacturing partition slots, wherein the partition slots extend through at least the third-color material layer to form a plurality of third-color sublayers, and third-color sublayers among the plurality of third-color sublayers whose vertical projections on the first substrate do not overlap a vertical projection of a first-color light-emitting unit among the first-color light-emitting units on the first substrate or a vertical projection of a second-color light-emitting unit among the second-color light-emitting units on the first substrate are third-color light-emitting units.

13. The preparation method according to claim 12, wherein combining the first substrate and the second substrate comprises:
forming a first transparent conductive layer on a side of the first-color light-emitting units and the second-color light-emitting units facing away from the first substrate;
forming a second transparent conductive layer on a surface of the third-color material layer facing away from the second substrate; and
bonding the second transparent conductive layer and the first transparent conductive layer to form a transparent conductive layer.

14. The preparation method according to claim 13, wherein preparing the first-color light-emitting units and the second-color light-emitting units on the side of the first substrate simultaneously, and disposing the first-color light-emitting units and the second-color light-emitting units in the same layer comprise:
preparing a mask layer on the first substrate, wherein the mask layer comprises a plurality of first mask holes and a plurality of second mask holes, and a dimension of the plurality of first mask holes is larger than a dimension of the plurality of second mask holes; and
preparing the first-color light-emitting units and the second-color light-emitting units in the plurality of first mask holes and the plurality of second mask holes simultaneously in a selective epitaxial growth manner, wherein each of the first-color light-emitting units is correspondingly formed in a respective one of the plurality of first mask holes, and each of the second-color light-emitting units is correspondingly formed in a respective one of the plurality of second mask holes.

15. The preparation method according to claim 14, wherein each of the first-color light-emitting units is a blue LED unit, a surface of each of the first-color light-emitting units facing away from the first substrate is an inclined surface, and the preparation method further comprises:
manufacturing a first sublayer on the first-color light-emitting units and the second-color light-emitting units;
forming a first passivation layer on the first sublayer and the mask layer;
planarizing the first passivation layer until a first sublayer on each of the first-color light-emitting units and a first sublayer on each of the second-color light-emitting units are exposed, wherein the first sublayer on each of the first-color light-emitting units forms an inclined conductive layer; and
manufacturing the first transparent conductive layer on the first sublayer and the first passivation layer.

16. The preparation method according to claim 13, wherein when the partition slots are manufactured, the preparation method further comprises:
manufacturing electrode vias corresponding to the first-color light-emitting units, the second-color light-emitting units, and the third-color light-emitting units;
forming a fourth passivation layer, wherein the fourth passivation layer fills the partition slots and the electrode vias, and covers a surface of the third-color light-emitting units facing away from the first substrate;
forming an electrode structure in a fourth passivation layer of the electrode vias, wherein the electrode structure comprises a plurality of first electrodes, and each of the plurality of first electrodes is electrically connected to the transparent conductive layer and a respective light-emitting unit among the first-color light-emitting units, the second-color light-emitting units, and the third-color light-emitting units; and
forming a drive unit layer on a side of the third-color light-emitting units facing away from the first substrate, wherein the drive unit layer comprises a plurality of drive units, and each of the plurality of drive units provides an electrical signal through the transparent conductive layer and a respective first electrode among the plurality of first electrodes for a respective light-emitting unit among the first-color light-emitting units, the second-color light-emitting units, and the third-color light-emitting units.

17. A preparation method of a full-color light-emitting diode (LED) structure, comprising:
preparing first-color light-emitting units and second-color light-emitting units on a side of a first substrate simultaneously, wherein the first-color light-emitting units and the second-color light-emitting units are disposed in a same layer;
preparing third-color light-emitting units on a side of a second substrate;
combining the first substrate and the second substrate such that the first-color light-emitting units, the second-color light-emitting units, and the third-color light-emitting units are disposed between the first substrate and the second substrate, wherein a vertical projection of a third-color light-emitting unit among the third-color light-emitting units on the first substrate does not overlap a vertical projection of a first-color light-emitting unit among the first-color light-emitting units on the first substrate or a vertical projection of a second-color light-emitting unit among the second-color light-emitting units on the first substrate; and
removing the second substrate.
